(19) United States
(12) Patent Application Publication
(10) Pub. No.: US 2001/0017420 A1
(43) Pub. Date: Aug. 30, 2001

(54) Electronic component and manufacturing method thereof

(75) Inventors: Hidemi Iwao, Tokyo (JP); Mayumi Arai, Tokyo (JP)

Correspondence Address: LOWE HAUPTMAN GOPSTEIN, GILMAN & BERNER, LLP, Suite 310, 1700 Diagonal Road, Alexandria, VA, 22314, US

(73) Assignee: Taiyo Yuden Co. Ltd.

(21) Appl. No.: 09/791,883

(22) Filed: Feb. 26, 2001

(30) Foreign Application Priority Data
Feb. 29, 2000 (JP) 2000-54127

(51) Int. Cl. H01L 23/48; H01L 23/52; H01L 29/40; H01L 21/20

(52) U.S. Cl. 257/758; 257/700; 257/690; 257/693; 438/381

(57) ABSTRACT

In an electronic component including: a sintered body with an internal electrode embedded; and an external electrode formed on the outer surface of this sintered body that is connected to the above internal electrode, a porous external electrode having numbers of pores is formed in the sintered body and thereafter the resin is impregnated through the pores. Thereby the pores of the external electrode are impregnated with a substance of the same sort as that of the buffer material as well as the buffer material interposes between the sintered body and the internal electrode.

### BACKGROUND OF THE INVENTION

So far, such kind of electronic components have been known which comprise a sintered body such as magnetic or dielectric sintered body with an internal electrode embedded and an external electrode formed on the surface of the sintered body so as to be connected to the lead part of the internal electrode. As an example of electronic component, a multilayer inductor will be described referring to FIG. 5. FIG. 5 is a sectional view explaining the structure of a conventional multilayer inductor.

As shown in FIG. 5, this multilayer inductor 100 comprises a magnetic sintered body 101 with an internal electrode 103 embedded as forming a coil and an external electrode 102 provided at both ends of the magnetic sintered body 101 so as to be connected to the lead part 103a of the above internal electrode 103.

By stacking ceramic green sheets printed with conductive paste, a multilayer body is prepared and is burned at high temperatures to produce a magnetic sintered body 101. By this burning step, a conductive paste and a ceramic green sheet are simultaneously burned to form an internal electrode 103 and a magnetic sintered body 101 respectively.

The external electrode 102 is formed by coating a metal paste mainly comprising Ag or the like to both ends of a sintered body 101 by the dipping or the like, then by burning the sintered body 101. Besides, on the surface of the external electrode 102, a plated layer 102a is formed by the electroplating or the like to improve the solder wetting property.

Meanwhile, generally, in electronic components as mentioned above, the sintered body and the internal electrode differ in thermal contraction coefficient. Accordingly, at the preparing of a layered product, at the printing of an external electrode, or at the soldering of the electronic component to a circuit substrate, a stress occurs in the sintered body. And, there is a problem that this stress causes a change in characteristics of the electronic component or occurrence of a crack in the sintered body. This problem is significant especially in an electronic component having an inductor element, e.g. in a multilayer inductor, a multilayer filter or the like. To be specific, in the above multilayer inductor 100, if a stress occurs on the border surface between the multilayer sintered body 101 and the internal electrode 103, an internal strain is generated by this stress, thereby deteriorating the magnetic property.

To solve such a problem, an electronic component in which the internal electronic component is peeled from a sintered body by increasing the thermal contraction coefficient in preparing the sintered body and a manufacturing method thereof are considered. In this electronic component, since voids are formed between the internal electrode and the sintered body, a stress occurring between the internal electrode and the sintered body is mitigated. Thereby, occurrence of cracks in the sintered body and fluctuation of characteristics can be reduced.

Besides, an electronic component in which a porous metal is adopted as the external electrode and- a manufacturing method thereof are considered. In this electronic component, a stress nonuniformly acting on a sintered body at the burning of an external electrode is mitigated and occurrence of cracks in the sintered body can be reduced.

In an electronic component in which voids are formed between the internal electrode and the sintered body, however, the magnetic substance and the internal electrode may contact each other on account of difference in expansion coefficient if they independently expand or contract under an external influence such as heat or magnetic field. At this time, there happened a problem that an internal strain is generated in the sintered body and characteristics are deteriorated.

Besides, with an electronic component in which voids are formed between the internal electrode and the sintered body and the external electrode is formed of a porous metal, there was a case where a plating solution intrudes into the above voids through the external electric field in applying the electroplating to the external electrode. In this case, the plating solution may remain after the plating even if washed and accordingly there was a problem that a corrosion or a poor conduction in the internal electrode was induced.

### BRIEF SUMMARY OF THE INVENTION

It is one object of the present invention to provide an electronic component proof against any external influence and stable in characteristics and a manufacturing thereof.

To attain this object, the present invention proposes an electronic component includes: a sintered body with an internal electrode embedded; and an external electrode formed on the outer surface of the sintered body connected to the above internal electrode, characterized in that a buffer material is interposed between the above sintered body and the above internal electrode, the above external electrode comprises a porous conductive member having numbers of pores, and the above pores of the external electrode are impregnated with a substance of the same sort as that of the above buffer material.

According to the present invention, since a buffer material is interposed between the sintered body and the internal electrode to prevent their direct contact, generation of a stress due to their contact is suppressed and the stress generated is also absorbed and mitigated by the buffer even when the internal electrode and the sintered body are expanded/contracted independently from each other. Thereby, even if a change in temperature, a change in magnetic field intensity or the like happens, a stress occurring inside the sintered body is minimized, thereby producing an electronic component stable in characteristics.

Besides, according to the present invention, since the external electrode comprises a porous conductive member, a stress acting on the sintered body at the burning of the external electrode is reduced. Furthermore, since the external electrode comprises a porous conductive member and its pores are impregnated with a substance of the same sort as that of the above buffer material, a plating solution or the like can be prevented from intruding into the sintered body at the formation of a plating layer on the external electrode.

Besides, to achieve the above object, the present invention proposes a method for manufacturing an electronic component includes: a sintered body with an internal electrode embedded; and an external electrode formed on an outer surface of the sintered body connected to the above internal electrode, comprising: a step of stacking a plurality of insulating sheets printed with an internal electrode to prepare a multilayer body; a step of burning the multilayer body to prepare a sintered body having voids between it and the internal electrode; a step of forming an external electrode comprising a porous conductive member on the surface of the sintered body so as to be electrically continuous and connected to the internal electrode; a step of impregnating a resin through pores of the external electrode into the above voids and into the pores of the external electrode; and a step of hardening the impregnated resin.

According to the present invention, the above electronic component can be securely and efficiently manufactured. That is, since a resin interposed between the internal resin and the sintered body and a resin impregnated into pores of the external electrode are formed in one step after the external electrode is formed, an electronic component can be efficiently manufactured.

Other objects, constitutions and effects of the present invention will be elucidated in the following detailed description than mentioned above.

### BRIEF DESCRIPTION OF THE SEVERAL VIEWS OF THE DRAWING

FIG. 1 is a perspective view of a multilayer chip inductor.

FIG. 2 is a sectional view of the multilayer chip inductor.

FIG. 3 is a flow chart showing manufacturing steps of the multilayer chip inductor.

FIG. 4 is a table showing measured result of the multilayer chip inductor.

FIG. 5 is a sectional view of a conventional multilayer chip inductor.

### DETAILED DESCRIPTION OF THE INVENTION

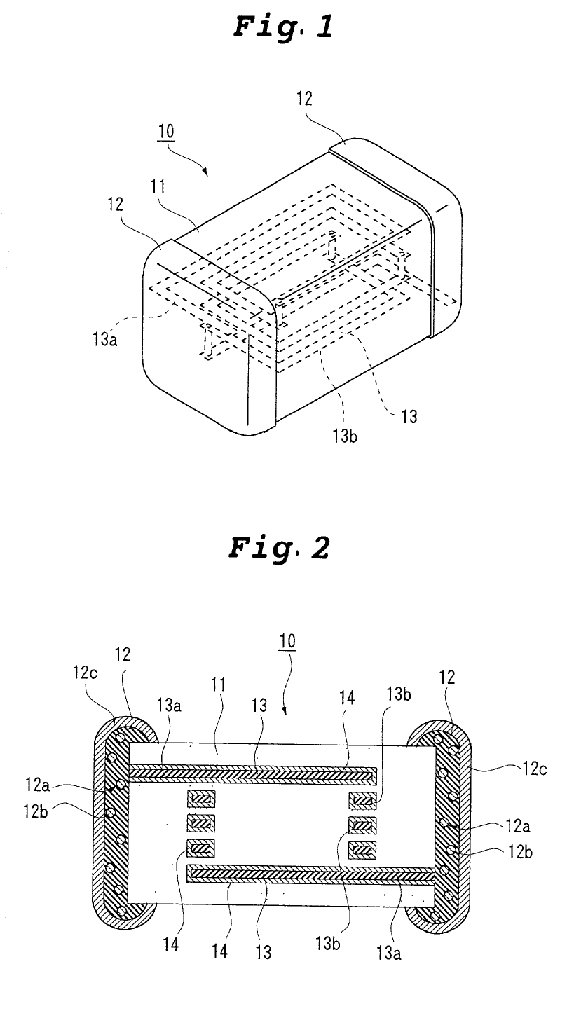

An electronic component according to one embodiment of the present invention will be described referring to FIGS. 1 and 2. In this embodiment, a multilayer chip inductor will be described as one example of electronic component. FIG. 1 is a perspective view of a multilayer chip inductor and FIG. 2 is a sectional view of the multilayer chip inductor.

As shown in FIG. 1, this multilayer chip inductor 10 comprises a magnetic sintered body 11 with an internal electrode 13 embedded as forming a coil and an external electrode 12 formed at both ends of the magnetic sintered body 11 of a rectangular parallelpiped shape and electrically continuous with and connected to the above internal electrode 103.

As described later, the magnetic sintered body 11 is obtained by stacking and burning a plurality of magnetic substance sheet. As magnetic sintered bodies 11, those of high magnetic permeability are preferable. One example is ferrite. Specifically, Ni—Zn—Cu ferrite, Ni—Zn ferrite, Cu—Zn ferrite and other examples can be enumerated. In this embodiment, Ni—Zn—Cu ferrite was used.

The internal electrode 13 comprises a lead part 13a exposed on both end surfaces of the magnetic sintered body 11 and a coil part 13b connected to the lead part 13a. To implement a high Q as an inductor, the internal electrode 13 is preferably low in electric resistance. For example, a conductive material, made of a noble metal such as Ag, Au or Pt or their alloy or a base metal such as Cu or Ni or their alloy, is considered. In this embodiment, Ag was used.

Between the magnetic sintered body 11 and the internal electrode 13, as shown in FIG. 2, a buffer material 14 is interposed. This buffer material 14 prevents the magnetic sintered body 11 and the internal conductor 13 from directly contacting and absorbs and mitigates the stress occurring between both of them. As this buffer material, a synthetic resin is used. Specifically, a thermosetting resin is preferred in production and for example, a silicon resin, an epoxy resin and a phenol resin are used. In this embodiment, the silicon resin was used.

The external electrode 12 is formed at the end part of the magnetic sintered body 11 so as to be connected to the lead part 13a of the above internal electrode 13. This external electrode 12 comprises a porous member having numbers of pores 12a. Here, the porosity of the external electrode 12 is preferably on the order of 10% to 30% and more preferably on that of 15% to 25%. Furthermore, an average grain size of the pore is preferably 0.3 to 4.0 μm and more preferably about 1.0 to 2.0 μm. As the material quality, the external electrode 12 comprises a material based on a metal such as, e.g. Ag. Besides, in pores 12a of the external electrode 12, a resin 12b mainly comprising the substance the same sort as that of the buffer material 14 is impregnated. Furthermore, on the surface layer of the external electrode 12, a plated layer 12c is formed. This plated layer 12c is formed, for example, by Ni plating or by solder plating.

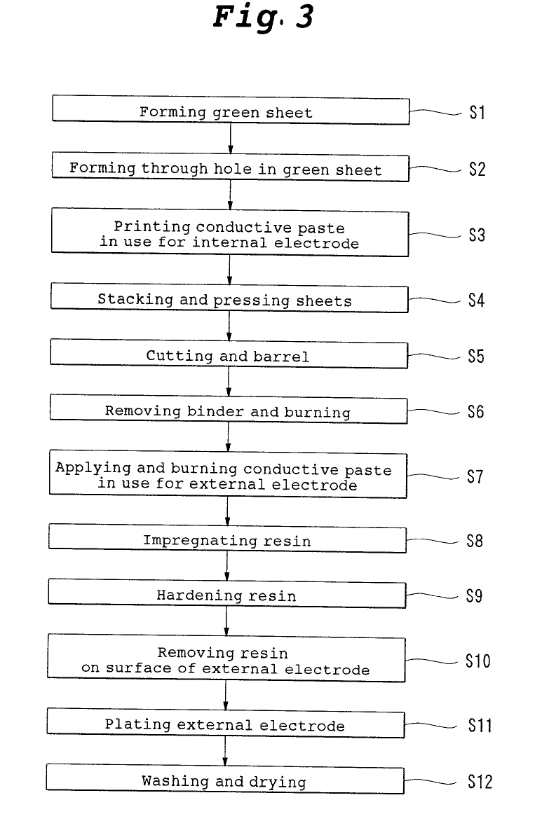

Next, a manufacturing method of this multilayer chip inductor 10 is described referring to FIG. 3. FIG. 3 is a flow chart showing the manufacturing steps of a multilayer chip inductor.

First of all, a ferrite sheet is fabricated (step S1). Specifically, to ferrite micro powder comprising FeO₂, CuO, ZnO and NiO after the calcination and grinding, ethyl cellulose and terpineol are added and this mixture is kneaded to obtain a ferrite paste. This ferrite paste is made into a sheet by using the doctor blade process or the like to obtain a ferrite sheet.

Next, in this ferrite sheet, a through hole is formed at a given position by using a punch, a laser or the like (step S2). Subsequently, on this ferrite sheet, a conductive paste for the internal electrode is printed in a given pattern (step S3). Here, the formation of a through hole and the print pattern of a conductive paste for the internal electrode are so arranged that a coil part for the internal electrode is formed by using a burned paste for the internal electrode.

Here, a conductive paste for internal electrode is used which is so composed as to have a larger contraction coefficient at the burning than the ferrite sheet. Specifically, the contraction coefficient at the burning is preferably on the order of 110% to 140% and more preferably on the order of 120% to 130% relative to that of the ferrite sheet. In this embodiment, a paste composed as follows was used. It is an Ag-based metal paste comprising 70 wt % of Ag particles (ball-shaped particles; average grain size: 0.3 μm), 9 wt % of ethyl cellulose, 19 wt % of butyl carbitol and 2 wt % of a viscosity intensifier.

Next, a plurality of ferrite sheets are stacked and pressed so that the respective sheets are connected through a through hole to each other to obtain a multilayer body (step S4). Subsequently, this is cut into a unit shape and further subjected to a barrel grinding (step S5).

Next, this multilayer body is heated in air at approx. 400° C. for 2 hr to remove the binder component in the multilayer body. Then, in air, it is burned at approx. 850 to 900° C. for 2 hr. Thereby, a magnetic sintered body with an internal electrode embedded is obtained (step S6). As mentioned above, the contraction coefficient of the conductive paste for the internal electrode at the burning is set greater than that of the ferrite sheet. Thus, by this burning process between the internal electrode made by burning the paste for the internal electrode and the magnetic sintered body made by burning the ferrite sheet, voids are formed.

Next, to both end parts of this magnetic sintered body, a conductive paste for the external electrode is applied by the dip process or the like. And, this magnetic sintered body is burned at approx. 800° C. in air for 2 hr. Thereby, an external electrode is formed on the outer surface of this magnetic sintered body (step S7). Here, a conductive paste for the external electrode so composed as to form numbers of pores after the burning is used as mentioned above. In this embodiment, a paste composed as follows was used. It is an Ag-based metal paste comprising 73 wt % of Ag particles (ball-shaped particles; average grain size: 0.5 μm), 4 wt % of glass frit (ZnO—B₂O₃—SiO₂), 10 wt % of ethyl cellulose, 13 wt % of a 1:1 mixed solution of butyl carbitol acetate and ethyl carbitol. By using such a metal paste, glass frit is gasified at the burning to form a porous metal member.

Next, the magnetic sintered body with an external electrode formed is impregnated with a resin (step S8). Specifically, into a vessel with a toluene-diluted silicone resin accommodated, the magnetic sintered body is thrown. And, this vessel is placed in a reduced-pressure container, the interior of which is reduced in pressure by means of a vacuum pump. The impregnation time was set to approx. 10 min. By this step, a silicone resin is impregnated through pores of the external electrode into the voids between the magnetic sintered body and the internal electrode and into the pores of the external electrode.

Next, the magnetic sintered body is taken out from the vessel and the impregnating silicone resin is hardened by heating at 200° C. in air for an hour (step S9).

Next, this magnetic sintered body is put into a rotary barrel and is subjected to barrel grinding and the silicone resin sticking to the surface of the external electrode is cleansed and removed (step S10). Then, electroplating is applied to the external electrode to form a plated layer (step S11). Finally, the plating solution is removed by the water washing and a multilayer chip inductor is obtained after the drying in the dry container at last (step S12).

By the above manufacturing steps, as shown in FIGS. 1 and 2, this multilayer chip inductor 10 gets a buffer material 14 comprising a silicone resin interposed between the internal electrode 13 and the magnetic sintered body 11. Besides, the external electrode 12 comprises a porous metal having numbers of pores 12a and the pores 12a are impregnated with the same resin 12b as employed in the buffer 14.

In such a multilayer chip inductor 10, since the buffer material 14 is interposed between the magnetic sintered body 11 and the internal electrode 13, i.e. since both of them are not in direct contact with each other, generation of a stress entailed by the contact between both of them is suppressed and the stress generated thus is also absorbed and mitigated by the buffer material 14 even when the internal electrode 13 and the magnetic sintered body 11 are expanded/contracted independently from each other. Thereby, a stress occurring inside the magnetic sintered body is minimized even if a change in temperature, a change in magnetic field intensity or the like occurs, so that magnetic characteristics are stabilized.

Besides, in this multilayer chip inductor 10, since the external electrode 12 comprises a porous conductive member, the stress acting on the magnetic sintered body 11 at the burning of the external electrode 12 is reduced. Furthermore, since the external electrode 12 comprises a porous conductive member and the pores 12a are impregnated with the same resin 12b as employed in the buffer 14, the plating solution can be prevented from intruding into the magnetic sintered body 101 at the forming of a plating layer on the external electrode 12.

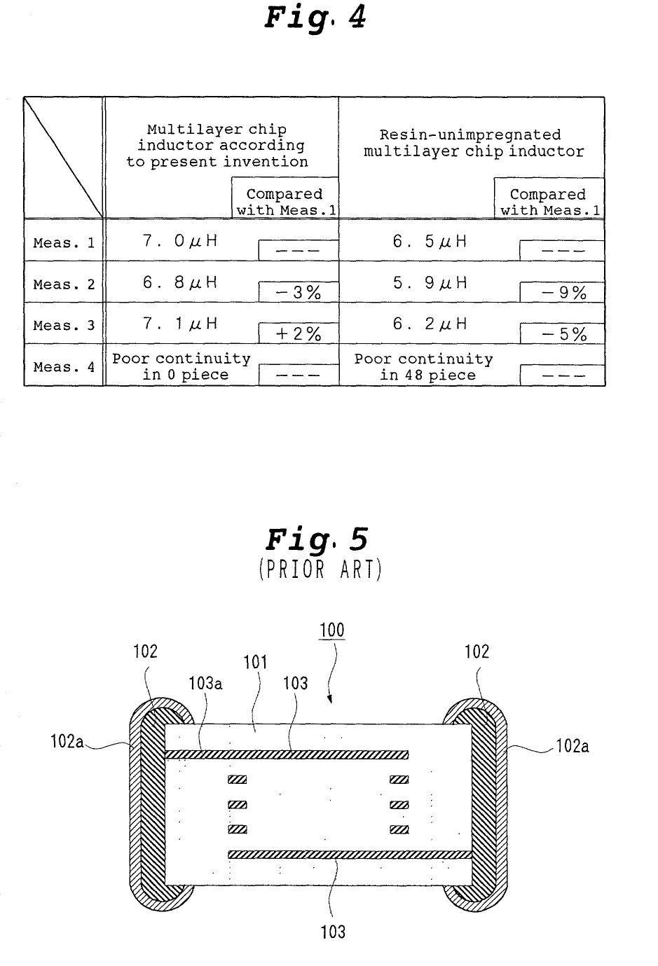

A great number of ones similar to this multilayer chip inductor 10 were manufactured by the above manufacturing method, out of which 100 multilayer chip inductors were picked up and subjected to the following four types of measurements to provide the measured result shown in the table of FIG. 4.

Measurement 1: to measure the average of inductance values (L values) under normal measuring conditions;

Measurement 2: to measure the average of L values after the approach of a 100 gauss magnet near multilayer chip inductors;

Measurement 3: to measure the average of L values after a 50 mA DC voltage is applied to multilayer chip inductors and released; and

Measurement 4: to measure the number of pieces poor in continuity when multilayer chip inductors are taken out from a humidity-resistant reservoir after put into the humidity-resistant reservoir and allowed to stand under conditions comprising a temperature of 85° C. and a humidity of 95% for 200 hr (number of faulty pieces among 100 pieces).

Incidentally, as the control, a multilayer chip inductor with electroplating applied to the external electrode without performing the resin impregnation step of S8 in the above manufacturing steps is referred.

By use of a multilayer chip inductor 10 according to the present invention, as shown by the measured result of measurements 1 to 3, the fluctuation of L values due to an external influence such as fluctuation in magnetic field was observed to decrease compared with a conventional multilayer chip inductor. Furthermore, as shown in the measured result of measurement 4, high durability was observed. Besides, in measurement 4, it was observed in a conventional article after the test that many corrosion portions were formed in the internal electrode. In this manner, the effect of the present invention could be confirmed.

Incidentally, the embodiment recorded in the present invention is exemplifying and not restrictive. The scope of the present invention is indicated by the appended claims and all changes and modifications that fall within the sense of these claims are to be included in the present invention.

In this embodiment, for example, multilayer chip inductor was described as one example of electronic component, but the present invention is not limited to this. The present invention can be implemented for whatever electronic component may have an internal electrode embedded in a sintered body and an external electrode connected to the internal electrode formed on the surface of the sintered body. For example, multilayer chip inductors, LC filters, capacitor arrays and inductor arrays are included. Especially, for an electronic component whose sintered body comprises a magnetic substance, including an inductance element, the present invention is effective, because a stress occurring between the internal electrode and the sintered body affects magnetic characteristics greatly.

What is claimed is:

1. An electronic component, comprising:
a sintered body with an internal electrode embedded; and
an external electrode formed on an outer surface of the sintered body and connected to said internal electrode,
wherein a buffer material is interposed between said sintered body and said internal electrode, and said external electrode comprises a porous conductive member having numbers of pores, and said pores of the external electrode are impregnated with a substance of a same sort as that of said buffer material.

2. The electronic component as set forth in claim 1, wherein the substance impregnated into said pores is a substance identical with said buffer material.

3. The electronic component as set forth in claim 1, wherein the substance impregnated into said pores is formed of a same raw material as said buffer material.

4. The electronic component as set forth in claim 1, wherein said buffer material and the substance impregnated into said pores are a resin.

5. The electronic component as set forth in claim 1, wherein said buffer material and the substance impregnated into said pores are a thermosetting resin.

6. The electronic component as set forth in claim 1, wherein said buffer material and the substance impregnated into said pores are a resin selected from a group comprising a silicone resin, an epoxy resin and a phenol resin.

7. The electronic component as set forth in claim 1, wherein said external electrode has a pore content ranging from 10% to 30%.

8. The electronic component as set forth in claim 1, wherein a plated layer is formed on a surface of said external electrode.

9. The electronic component as set forth in claim 1, wherein said sintered body comprises a magnetic substance.

10. A method for manufacturing an electronic component, including:
a sintered body with an internal electrode embedded; and
an external electrode formed on an outer surface of the sintered body connected to said internal electrode,
comprising:
a step of stacking a plurality of insulator sheets printed with a conductive paste in use for the internal electrode to fabricate a multilayer body;
a step of burning said multilayer body to fabricate a sintered body having voids between the sintered body and the internal electrode;
a step of forming the external electrode comprising a porous conductive member on the surface of said sintered body so as to be electrically continuous and connected to the internal electrode;
a step of impregnating a resin through pores of said external electrode into the said voids and into the pores of the external electrode; and
a step of hardening said impregnated resin.

11. The manufacturing method set forth in claim 10, wherein a thermosetting resin is used as said resin.

12. The manufacturing method as set forth in claim 10, wherein a resin selected from a group comprising a silicone resin, an epoxy resin and a phenol resin is used as said resin.

13. The manufacturing method as set forth in claim 10, further comprising:
a step of removing the resin sticking to the surface of said external electrode; and
a step of forming a plated layer on the surface of said external electrode after the hardening step of said resin.

14. The manufacturing method as set forth in claim 10, wherein a paste of being 110% to 140% relative to that of said insulator sheet in contraction coefficient is used as said conductive paste.

15. The manufacturing method as set forth in claim 10, wherein said sintered body comprises a magnetic substance.
